(19) United States
(12) Patent Application Publication
(10) Pub. No.: US 2024/0354476 A1
(43) Pub. Date: Oct. 24, 2024

(54) PRESSURE GAUGE PERFORMANCE PREDICTION OF WELLBORE CONDITIONS FOR PRESSURE TRANSIENT TESTING

(71) Applicant: Schlumberger Technology Corporation, Sugar Land, TX (US)

(72) Inventors: Jason Milne, Perth (AU); Bertrand Claude Theuveny, Paris (FR); Chen Tao, Sugar Land, TX (US); Hadrien Dumont, Paris (FR)

(21) Appl. No.: 18/642,146

(22) Filed: Apr. 22, 2024

Related U.S. Application Data
(60) Provisional application No. 63/497,455, filed on Apr. 21, 2023.

(51) Int. Cl. G06F 30/28

(52) U.S. Cl. CPC G06F 30/28

(57) ABSTRACT

Systems and methods presented herein provide for a gauge planner configured to provide a graphical user interface to a user computing device, to receive pressure gauge parameter data from the graphical user interface, to predict performance data for one or more pressure gauges based at least in part on the pressure gauge parameter data received from the graphical user interface, and to present the performance data for the one or more pressure gauges via the graphical user interface.

### CROSS-REFERENCE TO RELATED APPLICATIONS

This application claims the benefit of U.S. Provisional Application No. 63/497,455, entitled “PRESSURE GAUGE PERFORMANCE PREDICTION OF WELLBORE CONDITIONS FOR PRESSURE TRANSIENT TESTING,” filed Apr. 21, 2023, the disclosure of which is hereby incorporated herein by reference.

### BACKGROUND

The present disclosure generally relates to systems and methods for predicting performance of pressure gauges used in downhole well tools based at least in part on wellbore conditions.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as an admission of any kind.

Pressure transient testing with formation tester tools has existed for decades, but was historically constrained to formations of limited thickness and permeability. With advances in formation tester technology, the permeability-thickness envelope and the tested radius of investigation has increased. Formation testers may be conveyed on wireline and drill pipe, enabling highly efficient operations. However this can also expose pressure gauges to pressure and temperature variations over time, which can lead to gauge drift, for example.

### SUMMARY

A summary of certain embodiments described herein is set forth below. It should be understood that these aspects are presented merely to provide the reader with a brief summary of these certain embodiments and that these aspects are not intended to limit the scope of this disclosure.

Certain embodiments of the present disclosure include a method that includes providing, via a gauge planner, a graphical user interface to a user computing device. The method also includes receiving, via the gauge planner, pressure gauge parameter data from the graphical user interface. The method further includes predicting, via the gauge planner, performance data for one or more pressure gauges based at least in part on the pressure gauge parameter data received from the graphical user interface. In addition, the method includes presenting, via the gauge planner, the performance data for the one or more pressure gauges via the graphical user interface.

Certain embodiments of the present disclosure also include a non-transitory computer-readable media having processor-executable instructions stored thereon that, when executed by one or more processors, provide a gauge planner configured to provide a graphical user interface to a user computing device, to receive pressure gauge parameter data from the graphical user interface, to predict performance data for one or more pressure gauges based at least in part on the pressure gauge parameter data received from the graphical user interface, and to present the performance data for the one or more pressure gauges via the graphical user interface.

Certain embodiments of the present disclosure also include a control system having one or more processors configured to execute processor-executable instructions stored in memory media of the control system. The processor-executable instructions, when executed by the one or more processors, provide a gauge planner configured to provide a graphical user interface to a user computing device, to receive pressure gauge parameter data from the graphical user interface, to predict performance data for one or more pressure gauges based at least in part on the pressure gauge parameter data received from the graphical user interface, and to present the performance data for the one or more pressure gauges via the graphical user interface.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings, in which:

FIG. 1 illustrates a downhole tool being suspended in a wellbore traversing a formation by a cable, in accordance with embodiments of the present disclosure;

FIG. 2 illustrates a surface control system that may control the oil and gas well system of FIG. 1, in accordance with embodiments of the present disclosure;

FIG. 3 illustrates an embodiment of a tool control system illustrated in FIG. 1, in accordance with embodiments of the present disclosure;

FIG. 4 illustrates a simplified view of certain components of a formation testing or measurement tool, in accordance with embodiments of the present disclosure;

FIG. 5 illustrates an example graphical user interface of a gauge planner, in accordance with embodiments of the present disclosure; and

FIG. 6 is a flow diagram of a method of using a gauge planner, in accordance with embodiments of the present disclosure.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “connect,” “connection,” “connected,” “in connection with,” and “connecting” are used to mean “in direct connection with” or “in connection with via one or more elements”; and the term “set” is used to mean “one element” or “more than one element.” Further, the terms “couple,” “coupling,” “coupled,” “coupled together,” and “coupled with” are used to mean “directly coupled together” or “coupled together via one or more elements.”

In addition, as used herein, the terms “real time”, “real-time”, or “substantially real time” may be used interchangeably and are intended to describe operations (e.g., computing operations) that are performed without any human-perceivable interruption between operations. For example, as used herein, data relating to the systems described herein may be collected, transmitted, and/or used in control computations in “substantially real time” such that data readings, data transfers, and/or data processing steps occur once every second, once every 0.1 second, once every 0.01 second, or even more frequently, during operations of the systems (e.g., while the systems are operating). In addition, as used herein, the terms “continuous”, “continuously”, or “continually” are intended to describe operations that are performed without any significant interruption. For example, as used herein, control commands may be transmitted to certain equipment every five minutes, every minute, every 30 seconds, every 15 seconds, every 10 seconds, every 5 seconds, or even more often, such that operating parameters of the equipment may be adjusted without any significant interruption to the closed-loop control of the equipment. In addition, as used herein, the terms “automatic”, “automated”, “autonomous”, and so forth, are intended to describe operations that are performed are caused to be performed, for example, by a computing system (i.e., solely by the computing system, without human intervention).

The embodiments described herein provide systems and methods for predicting performance of pressure gauges used in downhole well tools based at least in part on wellbore conditions. As discussed above, formation testers may be conveyed on wireline and drill pipe, enabling highly efficient operations. However, this can also expose pressure gauges to pressure and temperature variations over time, which can lead to gauge drift, for example. The embodiments described herein address the quantification of pressure gauge dynamic response and performance, for improving pressure transient test design, execution, and analysis. In practice, all pressure sensors have response errors including short duration and long term drift, as well as temperature response effects which can impact gauge accuracy and resolution. The consequence of non-ideal pressure gauge responses can lead to uninterpretable data or to misinterpretation of reservoir effects. Reservoir engineers continue to emphasize the need to quantify the actual performance and limitations of pressure gauges in pressure transient testing in real well conditions for specific wellbore and reservoir environments.

The embodiments described herein provide a gauge planner that is configured to predict pressure gauge performance at specific downhole job conditions to enable operators to plan and control downhole well jobs more effectively and efficiently. The gauge planner described herein provides myriad advantages including, but not limited to, enabling prediction of performance of specific pressure gauges, facilitating the selection of the best pressure gauge for a particular downhole well job, optimization of downhole well operation workflows, highlighting advantages of the particular downhole well tools that incorporate the pressure gauges, gaining customer confidence, and so forth. As described in greater detail herein, the gauge performance factors that may be evaluated by the gauge planner may include, but are not limited to, pressure measurement accuracy, resolution, drift due to temperature changes, and so forth.

The gauge planner enables a method to separate the dynamic effects and gauge response errors from the true reservoir response. The method hinges on a model to quantify the dynamic uncertainty in a pressure gauge's output, thereby enabling estimation of the error in calibrated pressure over time in response to the recent history of pressure and temperature that the gauge has been exposed to. The dynamic uncertainty model has been established by integrating physics-based modelling with many years of calibration data, with short-term and medium-term drift measurements on thousands of high-performance pressure gauges passing through in-house calibration and test facilities. The dynamic uncertainty model may be applied to a pressure and temperature profile provided by a wellbore dynamics simulator for a specific downhole well job sequence. The pressure transient derivative may then be calculated from this simulated data together with the quantified uncertainty, yielding a worst-case impact of gauge response on a derivative plot, for example.

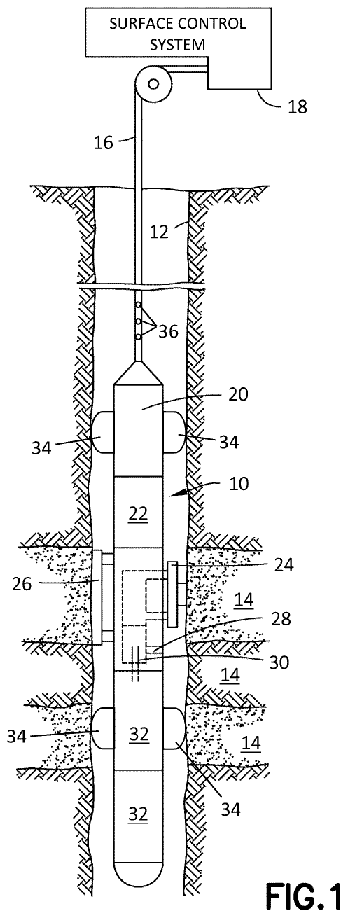

FIG. 1 illustrates a downhole tool 10 being suspended in a wellbore 12 traversing a subterranean formation 14 by a cable 16 that is spooled in a usual fashion on a suitable winch (not shown) on the formation surface. On the surface, the cable 16 may be electrically coupled to a surface control system 18 that is configured to at least partially control operation of the downhole tool 10 by communicating data and control signals to and from the downhole tool 10 via the cable 16, as described in greater detail herein. Although described primarily herein as using a cable 16 (e.g., wireline cable) to convey the downhole tool 10 into the wellbore 12, in other embodiments, other types of tool conveyance systems may be used to convey the downhole tool 10 into the wellbore 12, such as coiled tubing, pipe conveyance, and so forth. As illustrated, in certain embodiments, the downhole tool 10 includes an elongated body 20 that encloses a tool control system 22 that is configured to communicate with the surface control system 18 for the purpose of controlling operation of the downhole tool 10, as described in greater detail herein.

In particular, as described in greater detail herein, the downhole tool 10 may be a formation testing or measurement tool 10, and the elongated body 20 may include a fluid admitting assembly 24 and a tool anchoring member 26, which may be arranged on opposite lateral sides of the body 20. In certain embodiments, the fluid admitting assembly 24 is configured to selectively seal off or isolate selected portions of the wall of the wellbore 12 such that pressure or fluid communication with the adjacent formation 14 is established. In addition, in certain embodiments, the formation testing or measurement tool 10 includes a fluid analysis module 28 with a flow line 30 through which fluid collected from the formation 14 flows. The fluid may thereafter be expelled through a port (not shown) or may be directed to one or more fluid collecting chambers 32, which may receive and retain the fluids collected from the formation 14 or wellbore 12. As described in greater detail herein, the fluid admitting assembly 24, the fluid analysis module 28, and the flow path to the fluid collecting chambers 32 may be controlled by the control systems 18, 22. As used herein, the control systems 18, 22 may be collectively referred to as “the control system” in embodiments where they perform certain functions collectively in conjunction with each other.

In addition, in certain embodiments, the formation testing or measurement tool 10 may be associated with one or more inflatable packers 34 that are configured to inflate against the wellbore 12 to, for example, provide a seal between the inflatable packers 34 and the wellbore 12. In addition, in certain embodiments, the one or more inflatable packers 34 may isolate portions of the wellbore 12 to facilitate the collection of fluids via the formation testing or measurement tool 10. Although illustrated in FIG. 1 as including a formation testing or measurement tool 10 held in place within the wellbore 12 by one or more inflatable packers 34, in other embodiments, one or more inflatable packers 34 may isolate other types of downhole tools 10 within the wellbore 12.

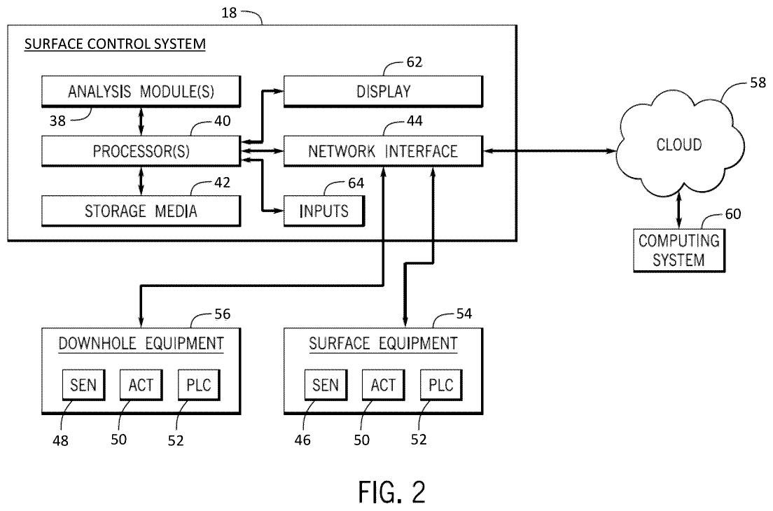

FIG. 2 illustrates an embodiment of the surface control system 18 illustrated in FIG. 1. In certain embodiments, the surface control system 18 may include one or more analysis modules 38 (e.g., a program of processor executable instructions and associated data) that may be configured to perform various functions of the embodiments described herein. In certain embodiments, to perform these various functions, an analysis module 38 executes on one or more processors 40 of the surface control system 18, which may be connected to one or more storage media 42 of the surface control system 18. Indeed, in certain embodiments, the one or more analysis modules 38 may be stored in the one or more storage media 42. In addition, as described in greater detail herein, the one or more analysis modules 38 may include a gauge planner, which utilizes a physics-based model to predict performance of various pressure gauges of formation testing or measurement tools 10 based, for example, on data relating to various downhole well conditions, as well as on characteristics of the pressure gauges themselves. For example, in certain embodiments, the one or more analysis modules 38 may implement artificial intelligence (AI) machine learning to learn certain relationships between various parameters relating to the performance of various pressure gauges based at least in part on the data relating to the various downhole well conditions, as well as on characteristics of the pressure gauges themselves.

In general, the gauge planner provided by the one or more modules 38 may take the form of software that is designed to the performance of a plurality of different types of pressure gauges, such as pressure gauges manufactured by different manufacturers, pressure gauges having different temperature and/or pressure ratings, and so forth. In addition, the gauge planner may utilize a physics-based model to predict performance of the plurality of different types of pressure gauges based on various different factors including, but not limited to: (1) temperature, pressure, overbalance, temperature gradient, and so forth, within the wellbore 12 (e.g., including real-time and/or historical data relating to these factors), (2) station time, buildup time, flow rate, drawdown pressure, and so forth (e.g., including real-time and/or historical data relating to these factors), and (3) properties of the subterranean formation 14, among other factors. In certain embodiments, the gauge planner may utilize various mathematical models that consider noise, deviations, and smoothing approaches. In certain embodiments, the algorithms utilized by the gauge planner may be implemented using mathematical analysis software (e.g., MATLAB) and the analysis results may be displayed in different scales, and either a single gauge may be analyzed, or multiple gauges may be compared with each other.

In certain embodiments, the one or more processors 40 may include a microprocessor, a microcontroller, a processor module or subsystem, a programmable integrated circuit, a programmable gate array, a digital signal processor (DSP), or another control or computing device. In certain embodiments, the one or more storage media 42 may be implemented as one or more non-transitory computer-readable or machine-readable storage media. In addition, in certain embodiments, the one or more storage media 42 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs); or other types of storage devices. Note that the processor-executable instructions and associated data of the analysis module(s) 38 may be provided on one computer-readable or machine-readable storage medium of the storage media 42 or, alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the one or more storage media 42 may be located either in the machine running the machine-readable instructions, or may be located at a remote site from which machine-readable instructions may be downloaded over a network for execution.

In certain embodiments, the processor(s) 40 may be connected to a network interface 44 of the surface control system 18 to allow the surface control system 18 to communicate with various surface sensors 46 and/or downhole sensors 48 described herein, as well as communicate with various actuators 50 and/or PLCs 52 of surface equipment 54 (e.g., surface pumps, valves, and so forth) and/or of downhole equipment 56 (e.g., the formation testing or measurement tool 10, the inflatable packers 34, electric submersible pumps, other downhole tools, and so forth) for the purpose of controlling operation of the oil and gas well system illustrated in FIG. 1. In certain embodiments, the network interface 44 may also facilitate the surface control system 18 to communicate data to a cloud-based service 58 (or other wired and/or wireless communication network) to, for example, archive the data or to enable external computing systems 60 (e.g., cloud-based computing systems, in certain embodiments) to access the data and/or to remotely interact with the surface control system 18. For example, in certain embodiments, some or all of the analysis modules 38 described in greater detail herein may be executed via cloud and edge deployments.

In certain embodiments, the surface control system 18 may include a display 62 configured to display a graphical user interface to present results of the operations described herein. In addition, in certain embodiments, the graphical user interface may present other information to operators of the equipment 54, 56 described herein. For example, the graphical user interface may include a dashboard configured to present visual information to the operators. In certain embodiments, the dashboard may show live (e.g., real-time) data as well as the results of the operations described herein.

In addition, in certain embodiments, the surface control system 18 may include one or more input devices 64 configured to enable operators to, for example, provide commands to the equipment 54, 56 described herein. For example, in certain embodiments, the formation testing or measurement tool 10 may provide information to the operators regarding the formation testing operations, and the operators may implement actions relating to the formation testing operations by manipulating the one or more input devices 64, as described in greater detail herein. In certain embodiments, the display 62 may include a touch screen interface configured to receive inputs from operators. For example, an operator may directly provide instructions to the formation testing or measurement tool 10 via the user interface, and the instructions may be output to the formation testing or measurement tool 10 via a controller and a communication system of the formation testing or measurement tool 10.

It should be appreciated that the surface control system 18 illustrated in FIG. 2 is only one example of a well control system, and that the surface control system 18 may have more or fewer components than shown, may combine additional components not depicted in the embodiment of FIG. 2, and/or the surface control system 18 may have a different configuration or arrangement of the components depicted in FIG. 2. In addition, the various components illustrated in FIG. 2 may be implemented in hardware, software, or a combination of both hardware and software, including one or more signal processing and/or application specific integrated circuits. Furthermore, the operations of the surface control system 18 as described herein may be implemented by running one or more functional modules in an information processing apparatus such as application specific chips, such as application-specific integrated circuits (ASICs), field-programmable gate arrays (FPGAs), programmable logic devices (PLDs), systems on a chip (SOCs), or other appropriate devices. These modules, combinations of these modules, and/or their combination with hardware are all included within the scope of the embodiments described herein.

In addition, as described above, the formation testing or measurement tool 10 includes a tool control system 22 (not shown) that controls the local functionality of the formation testing or measurement tool 10 and, in certain embodiments, the inflatable packers 34, as described in greater detail herein. In certain embodiments, the tool control system 22 of the formation testing or measurement tool 10 may communicate with the surface control system 18 such that the control systems 18, 22 collectively control operation of the formation testing or measurement tool 10 and/or the inflatable packers 34. As will be appreciated, the tool control system 22 of the formation testing or measurement tool 10 may include components that are substantially similar to the components of the surface control system 18 illustrated in FIG. 2, other than the display 62 and the input devices 64.

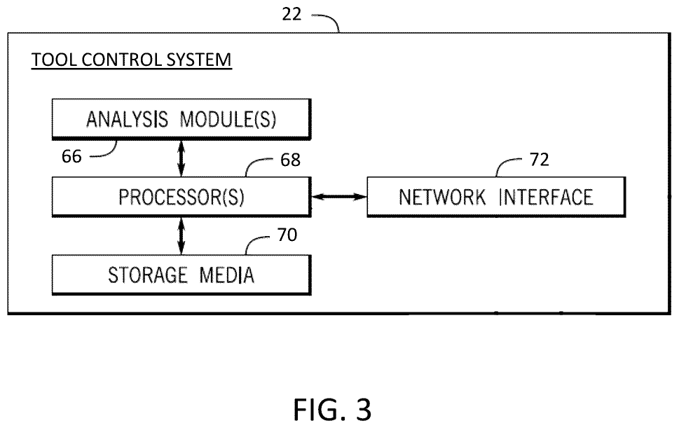

FIG. 3 illustrates an embodiment of the tool control system 22 illustrated in FIG. 1. In certain embodiments, the tool control system 22 may include one or more analysis modules 66 (e.g., a program of processor executable instructions and associated data) that may be configured to perform various functions of the embodiments described herein. In certain embodiments, to perform these various functions, an analysis module 66 executes on one or more processors 68 of the tool control system 22, which may be connected to one or more storage media 70 of the tool control system 22. Indeed, in certain embodiments, the one or more analysis modules 66 may be stored in the one or more storage media 70. In addition, in certain embodiments, the one or more analysis modules 66 of the tool control system 22 may be used in conjunction with the one or more analysis modules 38 of the surface control system 18 to enable the gauge planner described in greater detail herein. For example, in such embodiments, the one or more analysis modules 66 of the tool control system 22 may provide at least some of the computational functionality that enables the gauge planner that is also at least partially provided by the one or more analysis modules 38 of the surface control system 18, as described in greater detail herein. In other words, the one or more analysis modules 66 of the tool control system 22 and the one or more analysis modules 66 of the tool control system 22 may provide both global and local functionality of the gauge planner, respectively.

In certain embodiments, the one or more processors 68 may include a microprocessor, a microcontroller, a processor module or subsystem, a programmable integrated circuit, a programmable gate array, a digital signal processor (DSP), or another control or computing device. In certain embodiments, the one or more storage media 70 may be implemented as one or more non-transitory computer-readable or machine-readable storage media. In addition, in certain embodiments, the one or more storage media 70 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; or other types of storage devices. Such computer-readable or machine-readable storage medium or media are considered to be part of an article (or article of manufacture), which may refer to any manufactured single component or multiple components. In addition, in certain embodiments, the processor(s) 68 may be connected to a network interface 72 of the tool control system 22 to allow the tool control system 22 to communicate with the surface control system 18.

As described above, the embodiments described herein include a formation testing or measurement tool 10 configured to perform reservoir fluid analysis by drawing in formation fluid and testing the formation fluid downhole or collecting a sample of the formation fluid to bring to the surface. For example, in certain embodiments, the formation testing or measurement tool 10 may use the inflatable packers 34 to isolate a desired region of the wellbore 12 (e.g., at a desired depth) and establish fluid communication with the subterranean formation 14 surrounding the wellbore 12.

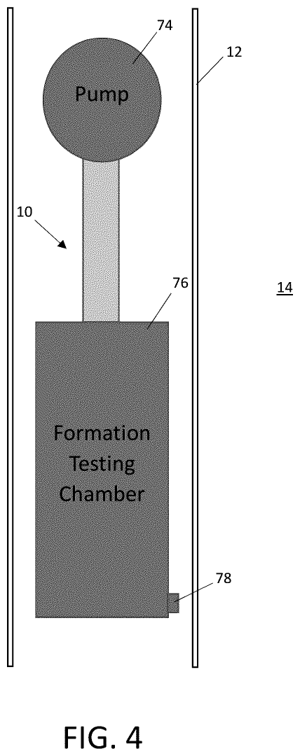

FIG. 4 illustrates a simplified view of certain components of the formation testing or measurement tool 10. Specifically, a pump 74 of the formation testing or measurement tool 10 may help draw sample fluids into the formation testing or measurement tool 10, which may be analyzed by the tool control system 22 while the sample fluids are disposed in a formation testing chamber 76 of the formation testing or measurement tool 10. In addition, in certain embodiments, the formation testing or measurement tool 10 may include one or more pressure gauges 78 configured to detect various pressures relating to the flow of fluids through the formation testing or measurement tool 10. As described in greater detail herein, the embodiments presented herein enable a gauge planner configured to utilize a physics-based model to predict performance of the one or more pressure gauges 78 of the formation testing or measurement tool 10. In particular, as described above, in certain embodiments, the one or more analysis modules 38 of the surface control system 18 and/or the one or more analysis modules 66 of the tool control system 22 may be executed to provide the functionality of the gauge planner described herein.

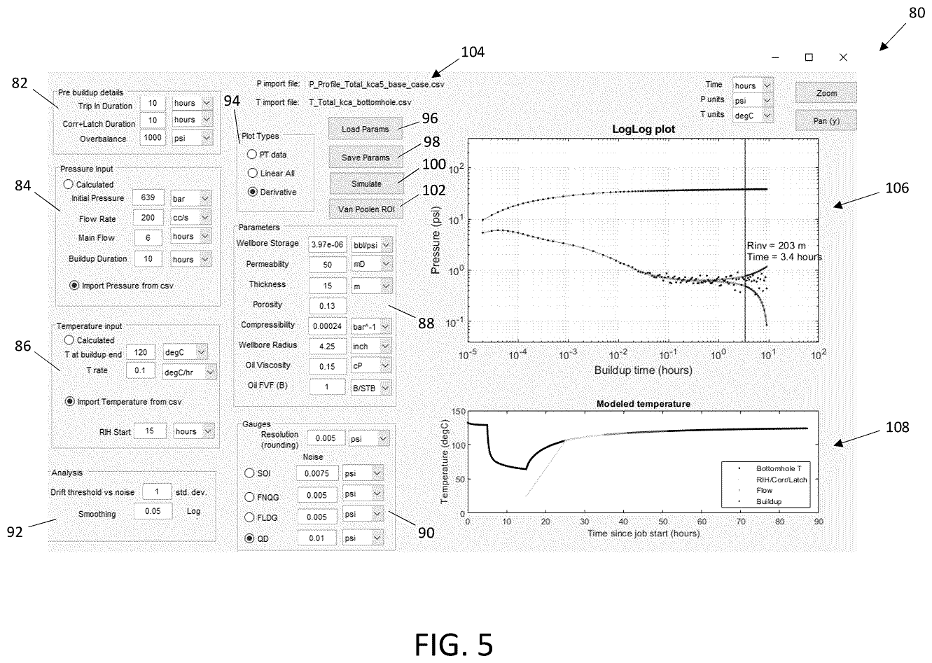

FIG. 5 illustrates an example graphical user interface 80 of the gauge planner described herein. As illustrated, the graphical user interface 80 includes a plurality of data panes that enable a user to view data that is either automatically imported for a particular downhole well job and/or manually entered by the user, and which may be modified by the user, in certain situations. For example, in certain embodiments, the graphical user interface 80 may include a Pre Buildup Details data pane 82 that shows data such as Trip In Duration, Corr-Latch Duration, Overbalance pressure, and so forth. In addition, in certain embodiments, the graphical user interface 80 may include a Pressure Input data pane 84 that, for example, enables a user to either calculate the pressure in the wellbore 12 (e.g., by entering an Initial Pressure, Flow Rate of fluids, duration of Main Flow, Buildup Duration, and so forth) or import data relating to the pressure in the wellbore 12 (e.g., from a .csv file). In addition, in certain embodiments, the graphical user interface 80 may include a Temperature Input data pane 86 that, for example, enables a user to either calculate the temperature in the wellbore 12 (e.g., by entering an Initial Temperature at buildup end, a temperature gradient (T rate), and so forth) or import data relating to the temperature in the wellbore 12 (e.g., from a .csv file). In addition, in certain embodiments, the graphical user interface 80 may include a Parameters data pane 88 that enables a user to either enter or modify data relating to conditions within the wellbore 12 and/or parameters of the subterranean formation 14 including, but not limited to, Wellbore Storage, Permeability of the subterranean formation 14, Thickness, Porosity of the subterranean formation 14, Compressibility of the subterranean formation 14, Wellbore Radius, Oil Viscosity, Oil FVF (i.e., formation volume factor, which is generally a ratio of oil volume in the subterranean formation 14 relative to oil volume at standard conditions), and so forth. In addition to the data panes 82, 84, 86, 88 described above, in certain embodiments, the graphical user interface 80 may also include a Gauges pane 90 that enables a user to select a type of pressure gauge 78 to be analyzed.

In addition, in certain embodiments, the graphical user interface 80 may also include various panes that enable a user to configure the analysis performed by the gauge planner described herein. For example, in certain embodiments, the graphical user interface 80 may include an Analysis pane 92 that enables a user to set various analysis parameters such as Drift Threshold vs. Noise, a Smoothing factor, and so forth. In addition, in certain embodiments, the graphical user interface 80 may also include a Plot Types pane 94 that enables a user to select the type of pressure and temperature plots that are presented via the graphical user interface 80 relating to performance of the pressure gauge being analyzed by the gauge planner.

In addition, in certain embodiments, the graphical user interface 80 may also include various buttons that enable a user to execute certain functionality of the gauge planner described herein. For example, in certain embodiments, the graphical user interface 80 may include a Load Params button 96 that enables a user to load parameters (e.g., those presented via the panes 82, 84, 86, 88, 90, 92, 94 of the graphical user interface 80) that were previously saved. In addition, in certain embodiments, the graphical user interface 80 may also include a Save Params button 98 that enables a user save parameters (e.g., those currently presented via the panes 82, 84, 86, 88, 90, 92, 94 of the graphical user interface 80). In addition, in certain embodiments, the graphical user interface 80 may also include a Simulate button 100 that enables a user to simulate the performance of a pressure gauge 78 using the currently selected parameters (e.g., those currently presented via the panes 82, 84, 86, 88, 90, 92, 94 of the graphical user interface 80). In addition, in certain embodiments, the graphical user interface 80 may also include an ROI button 102 that enables a user to calculate a return on investment relating to usage of a pressure gauge 78 currently being analyzed by the gauge planner described herein. In addition, in certain embodiments, the graphical user interface 80 may also display the file names of any imported pressure and/or temperature data files (e.g., that are imported via selections within the Pressure Input data pane 84 and/or the Temperature Input data pane 86, respectively, of the graphical user interface 80).

Once the Simulate button 100 is selected by a user, the gauge planner described herein may utilize a physics-based model to predict the performance of a pressure gauge 78 using the parameters currently presented via the panes 82, 84, 86, 88, 90, 92, 94 of the graphical user interface 80, and may present the results via a Pressure plot 106 and a Temperature plot 108 of the graphical user interface 80. In addition, in certain embodiments, the gauge planner described herein may automatically determine which pressure gauge 78, from a plurality of pressure gauges 78 analyzed by the gauge planner, will likely perform better for a given set of parameters (e.g., such as those presented via the panes 82, 84, 86, 88, 90, 92, 94 of the graphical user interface 80).

Furthermore, in certain embodiments, the analysis performed by the gauge planner described herein may be based on real-time data collected via surface sensors 46 and/or downhole sensors 48 during performance of a downhole well job using a formation testing or measurement tool 10 having a pressure gauge that is currently being analyzed by the gauge planner. In such embodiments, the analysis performed by the gauge planner may be used by one or more control systems 18, 22 to automatically adjust operational parameters of the formation testing or measurement tool 10 and/or other equipment 54, 56 in substantially real-time during the performance of the downhole well job based at least in part on the analysis performed by the gauge planner.

Using the gauge planner described herein, the well pressure and temperature profile may be simulated for a planned operational sequence and the gauge drift and resolution may quantified for that specific sequence for different gauge technologies. Sometimes, gauge drift may be easily mistaken for a reservoir boundary. By changing the operational sequence, the drift impact may be reduced to the extent that it no longer impacts the simulated pressure transient response for the target reservoir zone.

The ability of the gauge planner described herein to predict pressure gauge drift magnitude is new and unique. It is combined with a simulator to predict the gauge temperature and pressure exposure for operational sequences, creating an extremely powerful tool for understanding the impacts of real gauge behavior on pressure transient analysis. Using the gauge planner described herein, downhole well job sequences may now be designed to maximize pressure transient values while simultaneously minimizing the risk of misinterpretation.

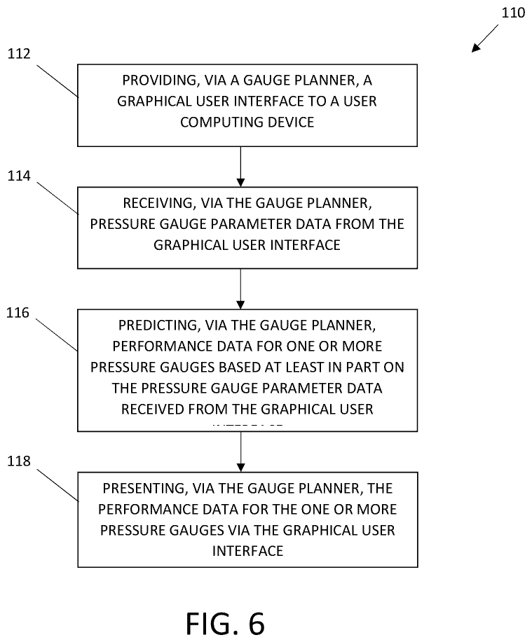

FIG. 6 is a flow diagram of a method 110 of using the gauge planner described in greater detail herein. As illustrated in FIG. 6, in certain embodiments, the method 110 may include providing, via a gauge planner, a graphical user interface 80 to a user computing device (step 112). In addition, in certain embodiments, the method 110 may also include receiving, via the gauge planner, pressure gauge parameter data from the graphical user interface 80 (step 114). In addition, in certain embodiments, the method 110 may also include predicting, via the gauge planner, performance data for one or more pressure gauges 78 based at least in part on the pressure gauge parameter data received from the graphical user interface 80 (step 116). In addition, in certain embodiments, the method 110 may include presenting, via the gauge planner, the performance data for the one or more pressure gauges 78 via the graphical user interface 80 (step 118).

In addition, in certain embodiments, the method 110 may include presenting, via the gauge planner, data relating to one or more downhole well conditions for a downhole well job via the graphical interface 80. In such embodiments, the pressure gauge parameter data received from the graphical user interface 80 may include the data relating to the one or more downhole well conditions for the downhole well job. In addition, in such embodiments, the data relating to the one or more downhole well conditions for the downhole well job may include wellbore storage, permeability of a subterranean formation, thickness, porosity of the subterranean formation, compressibility of the subterranean formation, wellbore radius, oil viscosity, a formation volume factor, or some combination thereof. In addition, in certain embodiments, the method 110 may include presenting, via the gauge planner, data relating to one or more characteristics of the one or more pressure gauges 78. In such embodiments, the pressure gauge parameter data received from the graphical user interface 80 may include the data relating to the one or more characteristics of the one or more pressure gauges 78.

In addition, in certain embodiments, the method 110 may include presenting, via the gauge planner, the performance data for the one or more pressure gauges 78 via a pressure plot 106 and/or a temperature plot 108 displayed by the graphical user interface 80. In addition, in certain embodiments, the performance data for the one or more pressure gauges 78 may include gauge drift and/or gauge resolution of the one or more pressure gauges 78.

In addition, in certain embodiments, the method 110 may include predicting, via the gauge planner, the performance data for the one or more pressure gauges 78 using a physics-based model. In addition, in certain embodiments, the method 110 may include predicting, via the gauge planner, the performance data for the one or more pressure gauges 78 using artificial intelligence machine learning techniques.

In addition, in certain embodiments, the gauge planner may be software at least partially executed by a surface control system and/or a tool control system of a formation testing or measurement tool. In addition, in certain embodiments, the method 110 may include automatically adjusting, via one or more control systems 18, 22 executing the gauge planner as software, one or more operational parameters of well equipment 54, 56, in substantially real-time during performance of a downhole well job, based at least in part on the performance data.

The specific embodiments described above have been illustrated by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A method, comprising:
providing, via a gauge planner, a graphical user interface to a user computing device;
receiving, via the gauge planner, pressure gauge parameter data from the graphical user interface;
predicting, via the gauge planner, performance data for one or more pressure gauges based at least in part on the pressure gauge parameter data received from the graphical user interface; and
presenting, via the gauge planner, the performance data for the one or more pressure gauges via the graphical user interface.

2. The method of claim 1, comprising presenting, via the gauge planner, data relating to one or more downhole well conditions for a downhole well job via the graphical interface, wherein the pressure gauge parameter data received from the graphical user interface comprises the data relating to the one or more downhole well conditions for the downhole well job.

3. The method of claim 2, wherein the data relating to the one or more downhole well conditions for the downhole well job comprises wellbore storage, permeability of a subterranean formation, thickness, porosity of the subterranean formation, compressibility of the subterranean formation, wellbore radius, oil viscosity, a formation volume factor, or some combination thereof.

4. The method of claim 1, comprising presenting, via the gauge planner, data relating to one or more characteristics of the one or more pressure gauges, wherein the pressure gauge parameter data received from the graphical user interface comprises the data relating to the one or more characteristics of the one or more pressure gauges.

5. The method of claim 1, comprising presenting, via the gauge planner, the performance data for the one or more pressure gauges via a pressure plot and/or a temperature plot displayed by the graphical user interface.

6. The method of claim 1, wherein the performance data for the one or more pressure gauges comprises gauge drift and/or gauge resolution of the one or more pressure gauges.

7. The method of claim 1, comprising predicting, via the gauge planner, the performance data for the one or more pressure gauges using a physics-based model.

8. The method of claim 1, comprising predicting, via the gauge planner, the performance data for the one or more pressure gauges using artificial intelligence machine learning techniques.

9. The method of claim 1, wherein the gauge planner comprises software at least partially executed by a surface control system.

10. The method of claim 1, wherein the gauge planner comprises software at least partially executed by a tool control system of a formation testing or measurement tool.

11. The method of claim 1, comprising automatically adjusting, via one or more control systems executing the gauge planner as software, one or more operational parameters of well equipment, in substantially real-time during performance of a downhole well job, based at least in part on the performance data.

12. A non-transitory computer-readable media having processor-executable instructions stored thereon that, when executed by one or more processors, provide a gauge planner configured to:
provide a graphical user interface to a user computing device;
receive pressure gauge parameter data from the graphical user interface;
predict performance data for one or more pressure gauges based at least in part on the pressure gauge parameter data received from the graphical user interface; and
present the performance data for the one or more pressure gauges via the graphical user interface.

13. The non-transitory computer-readable media of claim 12, wherein the gauge planner is configured to present data relating to one or more downhole well conditions for a downhole well job via the graphical interface, wherein the pressure gauge parameter data received from the graphical user interface comprises the data relating to the one or more downhole well conditions for the downhole well job.

14. The non-transitory computer-readable media of claim 13, wherein the data relating to the one or more downhole well conditions for the downhole well job comprises wellbore storage, permeability of a subterranean formation, thickness, porosity of the subterranean formation, compressibility of the subterranean formation, wellbore radius, oil viscosity, a formation volume factor, or some combination thereof.

15. The non-transitory computer-readable media of claim 12, wherein the gauge planner is configured to present data relating to one or more characteristics of the one or more pressure gauges, wherein the pressure gauge parameter data received from the graphical user interface comprises the data relating to the one or more characteristics of the one or more pressure gauges.

16. The non-transitory computer-readable media of claim 12, wherein the gauge planner is configured to present the performance data for the one or more pressure gauges via a pressure plot and/or a temperature plot displayed by the graphical user interface.

17. The non-transitory computer-readable media of claim 12, wherein the performance data for the one or more pressure gauges comprises gauge drift and/or gauge resolution of the one or more pressure gauges.

18. The non-transitory computer-readable media of claim 12, wherein the gauge planner is configured to predict the performance data for the one or more pressure gauges using a physics-based model.

19. The non-transitory computer-readable media of claim 12, wherein the gauge planner is configured to predict the performance data for the one or more pressure gauges using artificial intelligence machine learning techniques.

20. A control system, comprising:
one or more processors configured to execute processor-executable instructions stored in memory media of the control system, wherein the processor-executable instructions, when executed by the one or more processors, provide a gauge planner configured to:
provide a graphical user interface to a user computing device;
receive pressure gauge parameter data from the graphical user interface;
predict performance data for one or more pressure gauges based at least in part on the pressure gauge parameter data received from the graphical user interface; and
present the performance data for the one or more pressure gauges via the graphical user interface.
